(19) United States
(12) Patent Application Publication
(10) Pub. No.: US 2026/0190868 A1
(43) Pub. Date: Jul. 2, 2026

(54) MAJORANA QUANTUM BIT AND QUANTUM COMPUTER

(71) Applicant: FUJITSU LIMITED, Kawasaki-shi, Kanagawa (JP)

(72) Inventors: Manabu OHTOMO, Kawasaki (JP); Kenichi KAWAGUCHI, Ebina (JP)

(73) Assignee: FUJITSU LIMITED, Kawasaki-shi, Kanagawa (JP)

(21) Appl. No.: 18/607,609

(22) Filed: Mar. 18, 2024

(51) Int. Cl. H10N 60/12; H10N 60/01; H10N 60/80; H10N 60/85

(52) U.S. Cl. CPC H10N 60/12; H10N 60/0912; H10N 60/805; H10N 60/85

(57) ABSTRACT

A Majorana quantum bit includes: a first topological insulator layer including a first edge; a first s-wave superconductor layer; and a first layer provided between the first edge and the first s-wave superconductor layer and which allows cooper pairs to enter the first edge from the first s-wave superconductor layer.

### CROSS-REFERENCE TO RELATED APPLICATION

This application is a continuation application of International Application PCT/JP2021/034577 filed on Sep. 21, 2021 and designated the U.S., the entire contents of which are incorporated herein by reference.

### FIELD

The present disclosure relates to a Majorana quantum bit and a quantum computer.

### BACKGROUND

A quantum computer using Majorana particles has been studied. As a technique for generating the Majorana particles, a technique using a two dimensional topological insulator has been proposed. In this technique, an s-wave superconductor is brought into contact with a topological insulator, and Cooper pairs are tunneled from the s-wave superconductor to the topological insulator to generate the Majorana particles.

Related art is disclosed in Japanese National Publication of International Patent Application No. 2020-511780, U.S. Patent Application Publication No. 2020/0098990, Effects of large induced superconducting gap on semiconductor Majorana nanowires, W. S. Cole, et al., Physical Review B 92(17), 174511(2015), Coulomb-assisted braiding of Majorana fermions in a Josephson junction array, B. van Heck, et al., New Journal of Physics 14 (3), 035019 (2012), Minimal circuit for a flux-controlled Majorana qubit in a quantum spin-Hall insulator, B. v. Heck, et al., Physica Scripta T164, 014007 (2015), and Direct visualization of a two dimensional topological insulator in the single-layer 1T′-WTe2, Z. Y. Jia, et al., Physical Review B96 (4) (2017).

### SUMMARY

According to one aspect of the embodiments, a Majorana quantum bit includes: a first topological insulator layer including a first edge; a first s-wave superconductor layer; and a first layer provided between the first edge and the first s-wave superconductor layer and which allows cooper pairs to enter the first edge from the first s-wave superconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a top view illustrating a quantum bit according to a first embodiment.

FIG. 2 is a cross-sectional view illustrating the quantum bit according to the first embodiment.

FIG. 3 is a diagram illustrating a density of state of h-BN in contact with Nb.

FIG. 4 is a top view illustrating a quantum bit according to a reference example.

FIG. 5 is a cross-sectional view illustrating the quantum bit according to a reference example.

FIG. 6 is a diagram illustrating an intensity map of a spectral weight of WTe₂ in the reference example.

FIG. 7 is a diagram illustrating a band structure of WTe₂ and Nb in the reference example.

FIG. 8 is a diagram illustrating a band structure of WTe₂ which is not influenced from an outside.

FIG. 9 is a perspective view illustrating a quantum bit according to a second embodiment.

FIG. 10 is a top view illustrating a quantum bit according to the second embodiment.

FIG. 11 is a sectional view (part 1) illustrating the quantum bit according to the second embodiment;

FIG. 12 is a sectional view (part 2) illustrating the quantum bit according to the second embodiment.

FIG. 13 is a top view (part 1) illustrating a method of manufacturing the qubit 2 according to the second embodiment.

FIG. 14 is a top view (part 2) illustrating the method for manufacturing the qubit 2 according to the second embodiment.

FIG. 15 is a top view (part 3) illustrating the method of manufacturing the quantum bit 2 according to the second embodiment.

FIG. 16 is a top view (part 4) illustrating the method of manufacturing the quantum bit 2 according to the second embodiment.

FIG. 17 is a top view (part 5) illustrating the method of manufacturing the quantum bit 2 according to the second embodiment.

FIG. 18 is a top view (part 6) illustrating the method of manufacturing the quantum bit 2 according to the second embodiment;

FIG. 19 is a top view (part 7) illustrating the method of manufacturing the quantum bit 2 according to the second embodiment;

FIG. 20 is a top view (part 8) illustrating the method of manufacturing the quantum bit 2 according to the second embodiment;

FIG. 21 is a top view (part 9) illustrating the method of manufacturing the quantum bit 2 according to the second embodiment;

FIG. 22 is a top view (part 10) illustrating the method of manufacturing the quantum bit 2 according to the second embodiment.

FIG. 23 is a top view (part 11) illustrating the method of manufacturing the quantum bit 2 according to the second embodiment;

FIG. 24 is a schematic view (part 1) illustrating a method of manufacturing a quantum bit according to a third embodiment;

FIG. 25 is a schematic diagram (part 2) illustrating the method for manufacturing the quantum bit according to the third embodiment;

FIG. 26 is a schematic diagram (part 3) illustrating the method for manufacturing the quantum bit according to the third embodiment;

FIG. 27 is a schematic diagram (part 4) illustrating the method for manufacturing the quantum bit according to the third embodiment;

FIG. 28 is a schematic diagram (part 5) illustrating the method of manufacturing the quantum bit according to the third embodiment;

FIG. 29 is a schematic diagram illustrating a quantum bit according to a fourth embodiment.

FIG. 30 is a diagram illustrating a quantum computer according to a fifth embodiment;

FIG. 31 is a schematic diagram illustrating a quantum bit including a high-order topological insulator layer.

### DESCRIPTION OF EMBODIMENTS

In the technique using the two dimensional topological insulator, an electronic state of the topological insulator is damaged, and thus there is a possibility that the Majorana particles are not generated.

An object of the present disclosure is to provide a Majorana quantum bit and a quantum computer that may stably generate the Majorana particles.

Hereinafter, embodiments of the present disclosure will be described in detail with reference to the accompanying drawings. Note that in the specification and the drawings, components having substantially the same functional configuration are denoted by the same reference numerals, and, therefore, a redundant description thereof may be omitted.

### First Embodiment

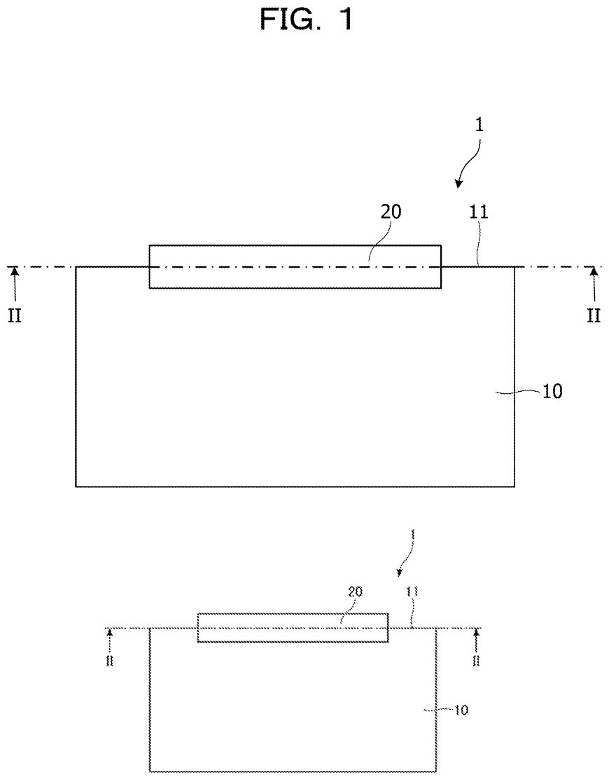

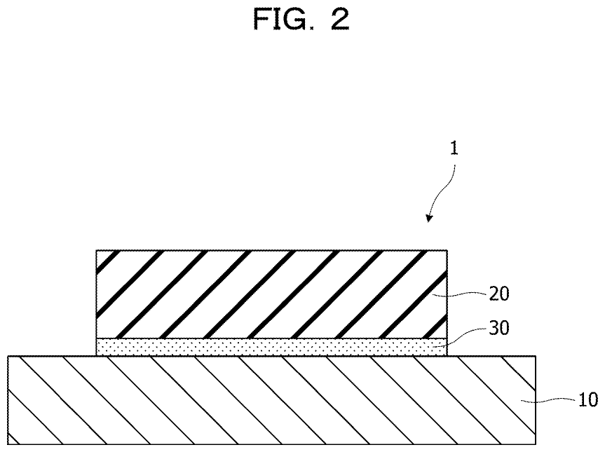

First, a first embodiment will be described. The first embodiment relates to a quantum bit including a two dimensional topological insulator. FIG. 1 is a top view illustrating a quantum bit according to the first embodiment. FIG. 2 is a cross-sectional view illustrating the quantum bit according to the first embodiment. FIG. 2 corresponds to a sectional view taken along a line II-II in FIG. 1.

As illustrated in FIGS. 1 and 2, the quantum bit 1 according to the first embodiment includes a topological insulator layer 10, an s-wave superconductor layer 20, and a cap layer 30.

The topological insulator layer 10 comprises an edge 11. The material of the topological insulator layer 10 is tungsten ditelluride (WTe₂). The material of the s-wave superconductor layer 20 is Nb. The material of the cap layer 30 is hexagonal boron nitride (h-BN). The cap layer 30 is provided between the edge 11 and the s-wave superconductor layer 20. The cap layer 30 allows a penetration of Cooper pairs from the s-wave superconductor layer 20 to the edge 11 by proximity effect. For example, the Cooper pairs may tunnel the cap layer 30 from the s-wave superconductor layer 20 and into the edge 11. When the Cooper pairs penetrate the edge 11, the topological insulator layer 10 becomes to function as a topological superconductor layer. The cap layer 30 is in direct contact with both the topological insulator layer 10 and the s-wave superconductor layer 20. The cap layer 30 is an example of a first layer.

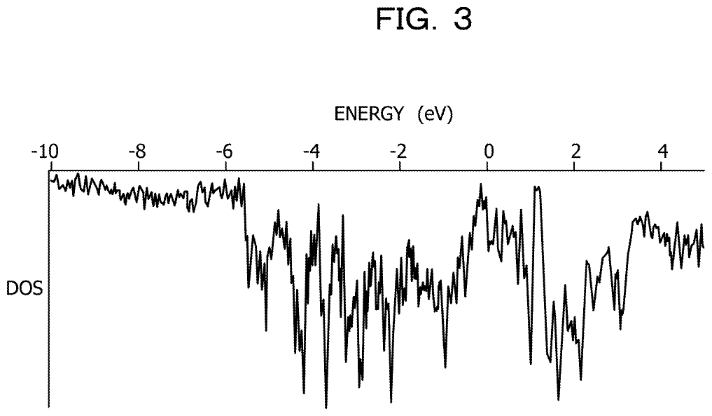

The h-BN itself, which is the material of the cap layer 30, is an insulating material having a band gap of about 6 eV. However, when the cap layer 30 becomes in contact with the s-wave superconductor layer 20 whose material is Nb, a chemical bond is formed between h-BN and Nb, and an electron state of h-BN becomes a metallic electron state. According to a simulation by an inventor, when the cap layer 30 becomes in direct contact with the s-wave superconductor layer 20, the shortest distance between Nb and h-BN is about 2.4 Å. FIG. 3 is a diagram illustrating the density of state (DOS) of h-BN in contact with Nb. As illustrated in FIG. 3, h-BN in contact with Nb has a density of state on a Fermi surface, and does not become a barrier to the Cooper pairs.

Also, according to the simulation of the inventor, when the cap layer 30 becomes in direct contact with the topological insulator layer 10, the shortest distance between WTe₂ and h-BN is about 3.0 Å. Therefore, no chemical bond exists between the cap layer 30 and the topological insulator layer 10, and a state is generated in which the cap layer 30 is physically adsorbed to the topological insulator layer 10. The cap layer 30 and the topological insulator layer 10 may be bonded to each other by van der Waals bonding.

In the first embodiment, since the cap layer 30 which is appropriate is provided between the edge 11 of the topological insulator layer 10 and the s-wave superconductor layer 20, the disturbance of the electronic state of the topological insulator layer 10 by the s-wave superconductor layer 20 may be suppressed, and the Majorana particles may be stably generated. Note that in the first embodiment, the shortest length between Nb and WTe₂ is about 5.4 Å.

The generated Majorana particles may be replaced by, for example, grounding or floating the s-wave superconductor layer 20.

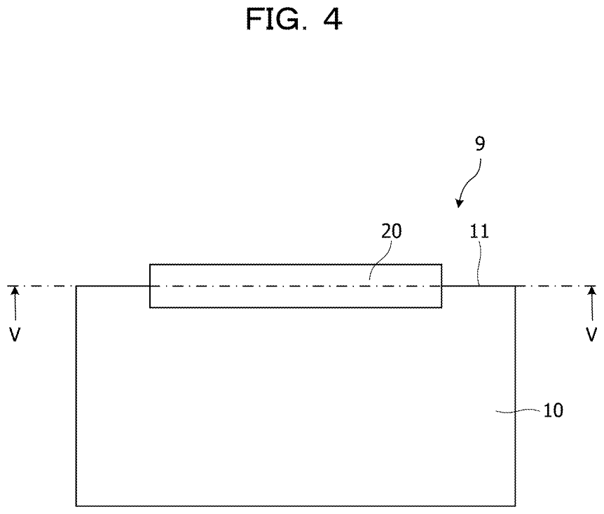

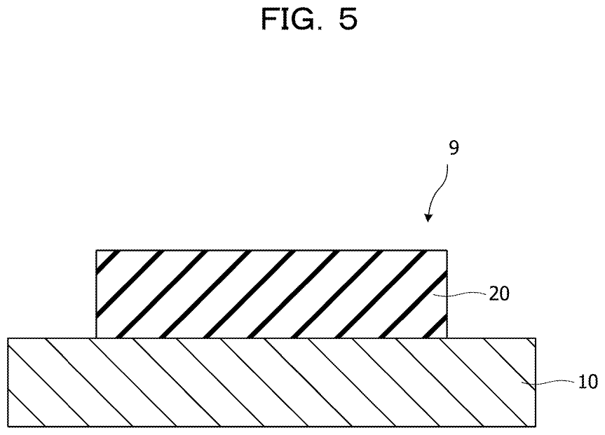

Here, a reference example will be described for comparison with the first embodiment. FIG. 4 is a top view illustrating a quantum bit according to a reference example. FIG. 5 is a cross-sectional view illustrating the quantum bit according to the reference example. FIG. 5 corresponds to a cross-sectional view taken along the line V-V in FIG. 4.

As illustrated in FIGS. 4 and 5, a quantum bit 9 according to the reference example does not include the cap layer 30, and the edge 11 of the topological insulator layer 10 and the s-wave superconductor layer 20 are in direct contact with each other. Other configurations are the same as those of the first embodiment.

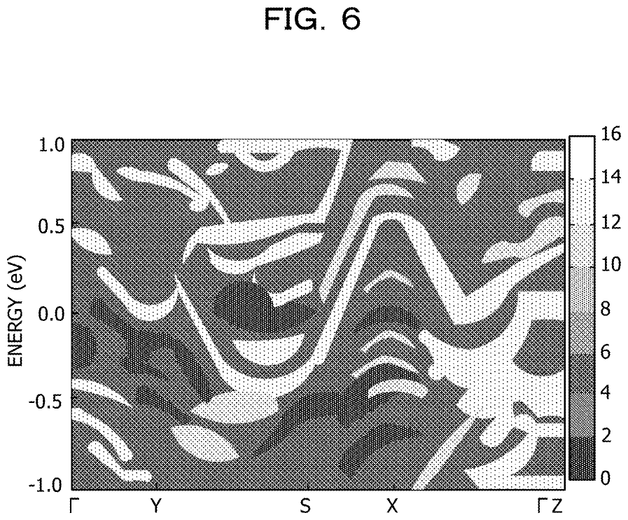

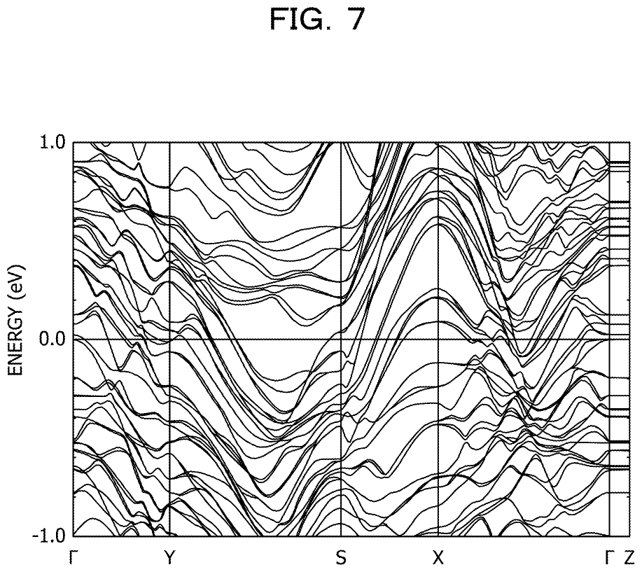

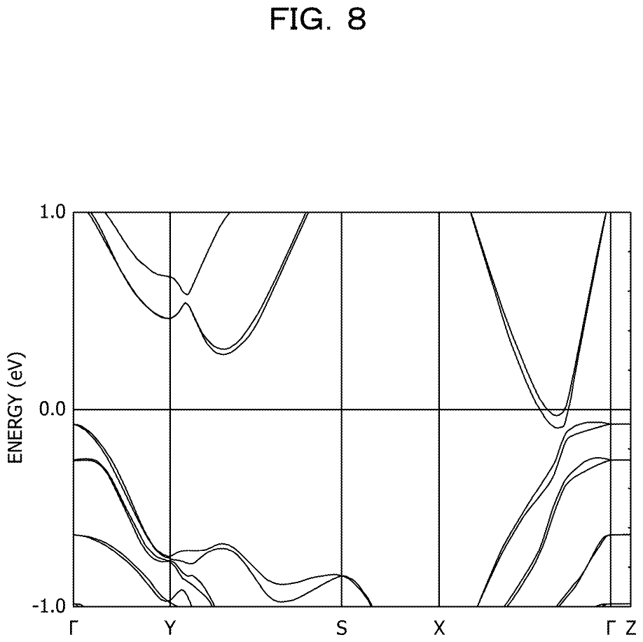

According to the simulation of the inventor, when the s-wave superconductor layer 20 is in direct contact with the topological insulator layer 10, the shortest length between Nb and the WTe₂ is only about 1.6 Å, and thus a chemical bond is formed between the topological insulator layer 10 and the s-wave superconductor layer 20. As a result, the electronic state of the topological insulator layer 10 is affected by the s-wave superconductor layer 20. FIG. 6 is a diagram illustrating an intensity map of a spectral weight of WTe₂ in the reference example. FIG. 7 is a diagram illustrating a band structure of WTe₂ and Nb in the reference example. FIG. 6 corresponds to a map obtained by extracting a contribution of WTe₂ in FIG. 7 as a weighting map. FIG. 8 is a diagram illustrating a band structure of a WTe₂ which is not affected from the outside.

As illustrated in FIG. 8, the WTe₂ of a single substance which is not affected from the outside, a difference in energy between an upper end of the valence band and a lower end of the conduction band is small. Therefore, in this state, WTe₂ may stably function as a topological insulator. However, as illustrated in FIGS. 6 and 7, when Nb and WTe₂ are in direct contact with each other, the band structure of WTe₂ is disturbed. Therefore, there is a possibility that WTe₂ may not function as the topological insulator. Therefore, in the quantum bit 9 according to the reference example, the electronic state of the topological insulator layer 10 is damaged, and there is a possibility that the Majorana particles are not be generated.

In contrast, in the first embodiment, as described above, since the cap layer 30 which is appropriate is provided, the disturbance of the electronic state of the topological insulator layer 10 by the s-wave superconductor layer 20 may be suppressed, and the Majorana particles may be stably generated. Note that, in the case where a layer serving as a barrier against the Cooper pairs is provided instead of the cap layer 30, the Cooper pairs may not enter the topological insulator layer 10, and thus the Majorana particles may not be generated.

### Second Embodiment

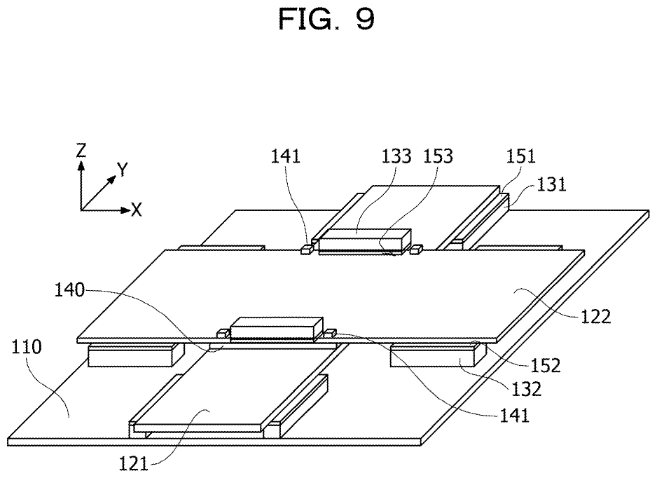

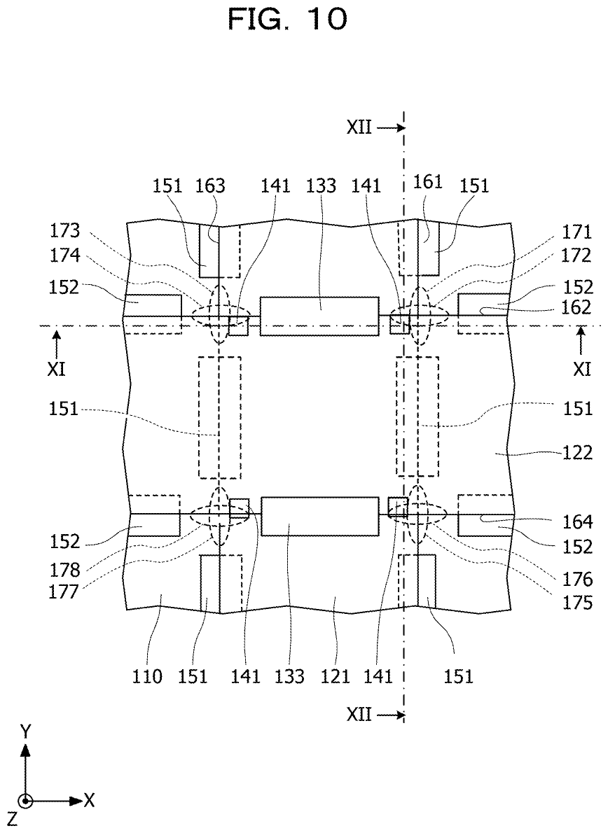

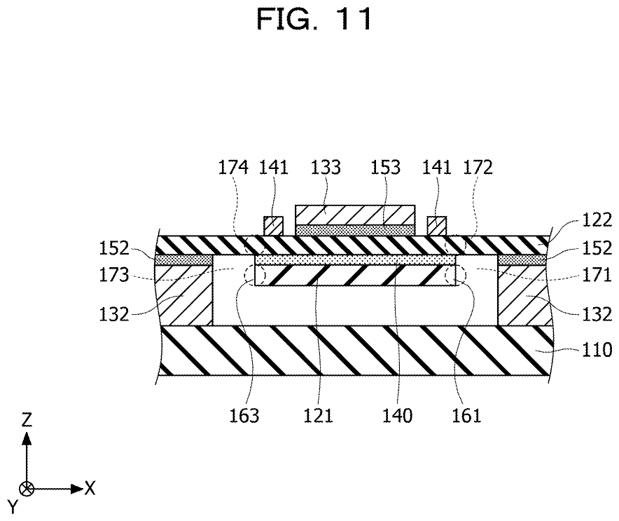

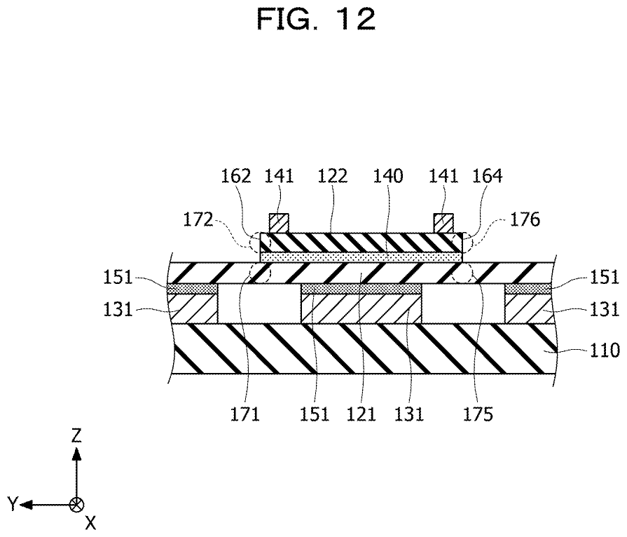

Next, a second embodiment will be described. The second embodiment relates to a quantum bit including a two dimensional topological insulator, to which the first embodiment is applied. FIG. 9 is a perspective view illustrating the quantum bit according to the second embodiment. FIG. 10 is a top view illustrated the quantum bit according to the second embodiment. FIGS. 11 and 12 are cross-sectional views illustrating the quantum bit according to the second embodiment. FIG. 11 corresponds to a cross-sectional view taken along the line XI-XI in FIG. 10. FIG. 12 corresponds to a cross-sectional view taken along line XII-XII in FIG. 10.

As illustrated in FIGS. 9 to 12, the quantum bit 2 according to the second embodiment includes a substrate 110, a lower topological insulator layer 121 extending in a Y-axis direction, and an upper topological insulator layer 122 extending in a X-axis direction. The substrate 110 is, for example, an insulating substrate such as an alumina substrate or a sapphire substrate. The X-axis direction and the Y-axis direction are directions orthogonal to a Z-axis direction perpendicular to a surface of the substrate 110. The Y-axis direction crosses the X-axis direction, and for example, the X-axis direction and the Y-axis direction are orthogonal to each other. In the present disclosure, viewing an object from the Z-axis direction may be referred to as a planar view. The Y-axis direction is an example of a first direction, and the X-axis direction is an example of a second direction.

The lower topological insulator layer 121 is, for example, a two dimensional topological insulator layer, and has a first edge 161 and a third edge 163 extending in the Y-axis direction. The first edge 161 is positioned on a +X side of the third edge 163. The lower topological insulator layer 121 may be formed of a single two dimensional topological insulator or may be formed of a plurality of two dimensional topological insulators stacked on each other. The material of the lower topological insulator layer 121 is, for example, tungsten ditelluride (WTe₂). Although not illustrated, a plurality of lower topological insulator layers 121 may be arranged in the X-axis direction side by side. The lower topological insulator layer 121 is an example of a first topological insulator layer.

The upper topological insulator layer 122 is, for example, a two dimensional topological insulator layer, and has a second edge 162 and a fourth edge 164 extending in the X-axis direction. The second edge 162 is positioned on a +Y side of the fourth edge 164. The upper topological insulator layer 122 may be formed of a single two dimensional topological insulator or may be formed of a plurality of two dimensional topological insulators stacked on each other. The material of the upper topological insulator layer 122 is, for example, tungsten ditelluride (WTe₂). Although not illustrated, a plurality of upper topological insulator layers 122 may be arranged in the Y-axis direction. The upper topological insulator layer 122 is an example of a second topological insulator layer.

A plurality of lower s-wave superconductor layers 131 are provided below the lower topological insulator layer 121. The lower s-wave superconductor layer 131 is provided along the first edge 161 and the third edge 163. An end portion of each lower s-wave superconductor layer 131 in the Y-axis direction is separated from the second edge 162 and the fourth edge 164 of the upper topological insulator layer 122 in a plan view. The lower s-wave superconductor layer 131 is, for example, an Nb layer. The lower s-wave superconductor layer 131 is an example of a first s-wave superconductor layer.

A cap layer 151 is provided over an upper surface of each lower s-wave superconductor layer 131. The cap layer 151 is in direct contact with an upper surface of the lower s-wave superconductor layer 131 and a lower surface of the lower topological insulator layer 121. The cap layer 151 is, for example, an h-BN layer. The h-BN layer includes one or more h-BNs stacked on each other. The cap layer 151 is provided between the first edge 161 or the third edge 163 and the lower s-wave superconductor layer 131. There is no chemical bond between the cap layer 151 and the lower topological insulator layer 121, and the cap layer 151 is in a state in which the cap layer 151 is physically adsorbed to the lower topological insulator layer 121. The cap layer 151 and the lower topological insulator layer 121 may be bonded to each other by a van der Waals bonding. A penetration of the Cooper pairs, via the cap layer 151, from the lower s-wave superconductor layer 131 to the first edge 161 or the third edge 163 due to the proximity effect may be enabled. For example, the Cooper pairs may tunnel through the cap layer 151 from the lower s-wave superconductor layer 131 and penetrate into the first edge 161 or the third edge 163. When the Cooper pairs penetrate the first edge 161 or the third edge 163, the lower topological insulator layer 121 becomes to function as a topological superconductor layer. The cap layer 151 is an example of a first layer.

A plurality of upper s-wave superconductor layers 132 are provided below the upper topological insulator layer 122. The upper s-wave superconductor layers 132 are provided along the second edge 162 and the fourth edge 164. An end portion of each upper s-wave superconductor layer 132 in the X-axis direction is separated from the first edge 161 and the third edge 163 of the lower topological insulator layer 121 in a plan view. The upper s-wave superconductor layers 132 are, for example, an Nb layer. The upper s-wave superconductor layer 132 is an example of a 2s wave superconductor layer.

A cap layer 152 is provided on an upper surface of each upper s-wave superconductor layer 132. The cap layer 152 is in direct contact with the upper surface of the upper s-wave superconductor layer 132 and a lower surface of the upper topological insulator layer 122. The cap layer 152 is, for example, an h-BN layer. The h-BN layer includes one or more h-BNs stacked on each other. The cap layer 152 is provided between the second edge 162 or the fourth edge 164 and the upper s-wave superconductor layer 132. There is no chemical bond between the cap layer 152 and the upper topological insulator layer 122, and the cap layer 152 is in a state in which the cap layer 152 is physically adsorbed to the upper topological insulator layer 122. The cap layer 152 and the upper topological insulator layer 122 may be bonded to each other by the van der Waals bonding. A penetration of the Cooper pairs, via the cap layer 152, from the upper s-wave superconductor layer 132 to the second edge 162 or the fourth edge 164 due to the proximity effect may be enabled. For example, the Cooper pairs may tunnel through the cap layer 152 from the upper s-wave superconductor layer 132 and penetrate the second edge 162 or the fourth edge 164. When the Cooper pairs penetrate the second edge 162 or the fourth edge 164, the upper topological insulator layer 122 becomes to function as a topological superconductor layer. The cap layer 152 is an example of a second layer.

A plurality of upper s-wave superconductor layers 133 are provided above the upper topological insulator layer 122. The upper s-wave superconductor layers 133 are provided along the second edge 162 and the fourth edge 164. An end portion of each upper s-wave superconductor layer 133 in the X-axis direction is separated from the first edge 161 and the third edge 163 of the lower topological insulator layer 121 in a plan view. The upper s-wave superconductor layers 133 are, for example, an Nb layer. The upper s-wave superconductor layer 133 is an example of a 2s wave superconductor layer.

A cap layer 153 is provided on the lower surface of each upper s-wave superconductor layer 133. The cap layer 153 is in direct contact with a lower surface of the upper s-wave superconductor layer 133 and an upper surface of the upper topological insulator layer 122. The cap layer 153 is, for example, an h-BN layer. The h-BN layer includes one h-BN or a plurality of h-BNs stacked on each other. The cap layer 153 is provided between the second edge 162 or the fourth edge 164 and the upper s-wave superconductor layer 133. There is no chemical bond between the cap layer 153 and the upper topological insulator layer 122, and the cap layer 153 is in a state in which the cap layer 153 is physically adsorbed to the upper topological insulator layer 122. The cap layer 153 and the upper topological insulator layer 122 may be bonded to each other by the van der Waals bonding. A penetration of the allows Cooper pairs, via the cap layer 153, from the upper s-wave superconductor layer 133 to the second edge 162 or the fourth edge 164 due to the proximity effect may be enabled. For example, the Cooper pairs may tunnel through the cap layer 153 from the upper s-wave superconductor layer 133 and penetrate the second edge 162 or the fourth edge 164. When the Cooper pairs penetrate the second edge 162 or the fourth edge 164, the upper topological insulator layer 122 becomes to function as a topological superconductor layer. The cap layer 153 is an example of a second layer.

For example, in a plan view, the upper s-wave superconductor layer 133 and the cap layer 153 are provided in a region in which the upper topological insulator layer 122 overlaps with the lower topological insulator layer 121, and the upper s-wave superconductor layer 132 and the cap layer 152 are provided in a region away from the lower topological insulator layer 121.

An etching stopper 140 is provided between the lower topological insulator layer 121 and the upper topological insulator layer 122. The material of the etching stopper 140 is, for example, graphene or graphite. When the material of the etching stopper 140 is graphite, the etching stopper 106 is preferably as thin as possible, and is preferably, for example, 5 nm or thinner. This is because the Majorana particles tunnel through the etching stopper 140 between the lower topological insulator layer 121 and the upper topological insulator layer 122.

A plurality of magnetic electrodes 141 are provided over the upper topological insulator layer 122. The magnetic electrodes 141 are provided, for example, between the upper s-wave superconductor layer 133 and the second edge 162 and between the upper s-wave superconductor layer 133 and the fourth edge 164 within a range where the lower topological insulator layer 121 and the upper topological insulator layer 122 overlap each other in a plan view. The magnetic electrodes 141 generate a magnetic field that extends the upper topological insulator layer 122 and the lower topological insulator layer 121. The material of the magnetic electrode 141 is, for example, Fe, Co, or Ni. The magnetic electrode 141 is an example of a first magnetic layer and a second magnetic layer.

In the quantum bit 2, the Majorana particles may exist in a portion between two lower s-wave superconductor layers 131 which are adjacent to each other in a plan view of the first edge 161 and a portion between two lower s-wave superconductor layers 131 which are adjacent to each other in a plan view of the third edge 163. Further, for example, in a portion where these Majorana particles may exist, the portion where the first edge 161 overlaps with the second edge 162 functions as a first region 171, and the portion where the third edge 163 overlaps with the second edge 162 functions as a third region 173. In addition, for example, in the portion where these Majorana particles may exist, the portion where the first edge 161 overlaps with the fourth edge 164 functions as a fifth region 175, and the portion where the third edge 163 overlaps with the fourth edge 164 functions as a seventh region 177.

Similarly, the Majorana particles may exist in a portion between the upper s-wave superconductor layer 132 and the upper s-wave superconductor layer 133 which are adjacent to each other in a plan view of the second edge 162 and in a portion between the upper s-wave superconductor layer 132 and the upper s-wave superconductor layer 133 which are adjacent to each other in a plan view of the fourth edge 164. Further, for example, in the portion where the Majorana particles may exist, a portion where the second edge 162 overlaps with the first edge 161 functions as a second region 172, and a portion where the fourth edge 164 overlaps with the first edge 161 functions as a sixth region 176. In addition, in the portion where these Majorana particles may exist, the portion where the second edge 162 overlaps with the third edge 163 functions as a fourth region 174, and the portion where the fourth edge 164 overlaps with the third edge 163 functions as a eighth region 178.

The Majorana particles present in the first region 171 and the Majorana particles present in the second region 172 may pass through the etching stopper 140 by a tunnel effect and interact with each other. Thus, both of the Majorana particles may be considered as a single Majorana particle. The same also applies to a set of the third region 173 and the fourth region 174, a set of the fifth region 175 and the sixth region 176, and a set of the seventh region 177 and the eighth region 178.

As described above, in the quantum bit 2, the Majorana particles generated in the lower topological insulator layer 121 and the Majorana particles generated in the upper topological insulator layer 122 may be easily caused to interact with each other.

Further, a cap layer 151 is provided over the upper surface of each lower s-wave superconductor layer 131, a cap layer 152 is provided over the upper surface of each upper s-wave superconductor layer 132, and a cap layer 153 is provided on the lower surface of each upper s-wave superconductor layer 133. Therefore, as in the first embodiment, the disturbance of the electron state of each of the lower topological insulator layer 121 and the upper topological insulator layer 122 may be suppressed, and the Majorana particles may be stably generated. The generated Majorana particles may be replaced by grounding or floating the s-wave superconductor layers 131 to 133, for example.

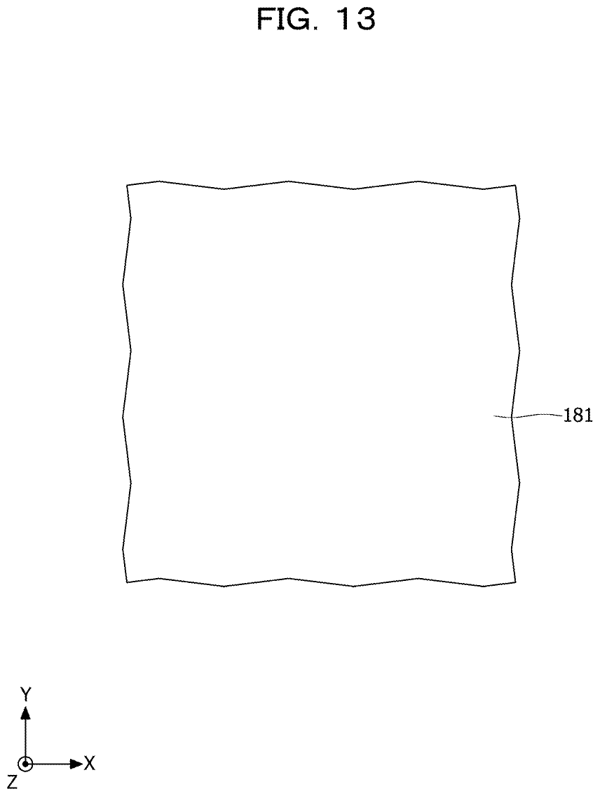

Next, a method of manufacturing the quantum bit 2 according to the second embodiment will be described. FIGS. 13 to 23 are top views illustrating the method of manufacturing the quantum bit 2 according to the second embodiment.

First, as illustrated in FIG. 13, an Nb layer 181 is formed over a substrate 110. The Nb layer 181 may be formed by, for example, a vapor deposition method or the like.

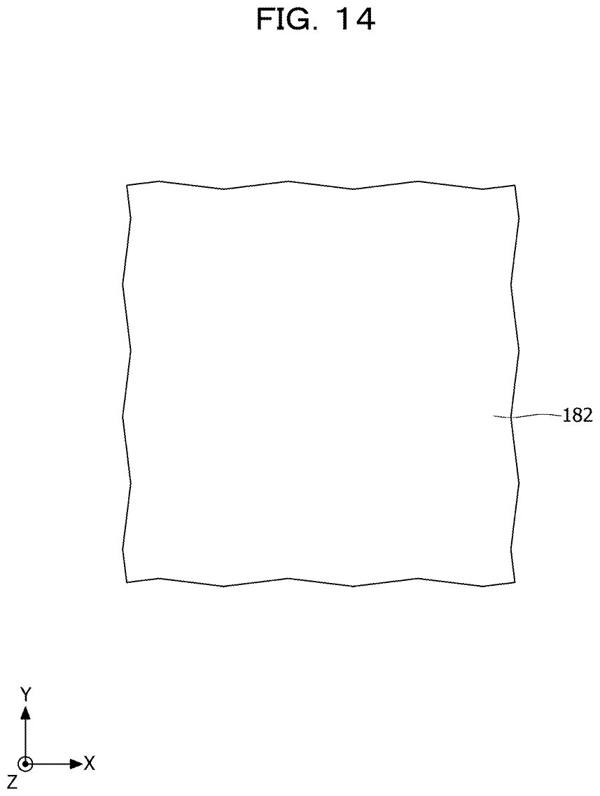

Next, as illustrated in FIG. 14, an h-BN layer 182 is formed over the Nb layer 181. The h-BN layer 182 may be formed by, for example, a chemical vapor deposition (CVD) method or the like.

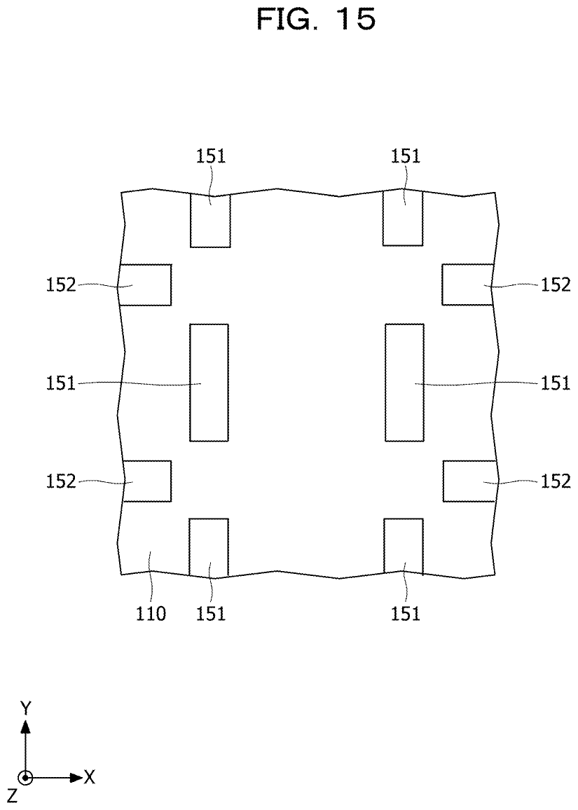

Thereafter, as illustrated in FIG. 15, a laminate of the Nb layer 181 and the h-BN layer 182 is processed to form a laminate of the lower s-wave superconductor layer 131 and the cap layer 151 and a laminate of the upper s-wave superconductor layer 132 and the cap layer 152 (see FIGS. 11 and 12). The cap layers 151 and 152 may function as protective layers for the lower s-wave superconductor layer 131 and the upper s-wave superconductor layer 132, respectively, and may suppress an oxidation of the surfaces of the lower s-wave superconductor layer 131 and the upper s-wave superconductor layer 132 in subsequent processes.

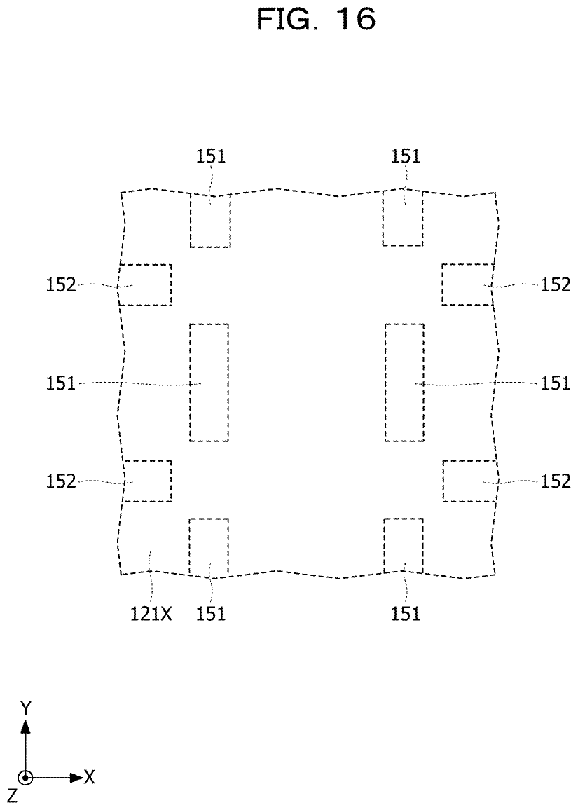

Subsequently, as illustrated in FIG. 16, a two dimensional topological insulator layer 121X is provided over the substrate 110 so as to cover the laminate of the lower s-wave superconductor layer 131 and the cap layer 151 and the laminate of the upper s-wave superconductor layer 132 and the cap layer 152. The two dimensional topological insulator layer 121X may be provided by, for example, separately growing the two dimensional topological insulator layer 121X on a growing substrate (not illustrated) and transferring the two dimensional topological insulating layer 121X from the growing substrate.

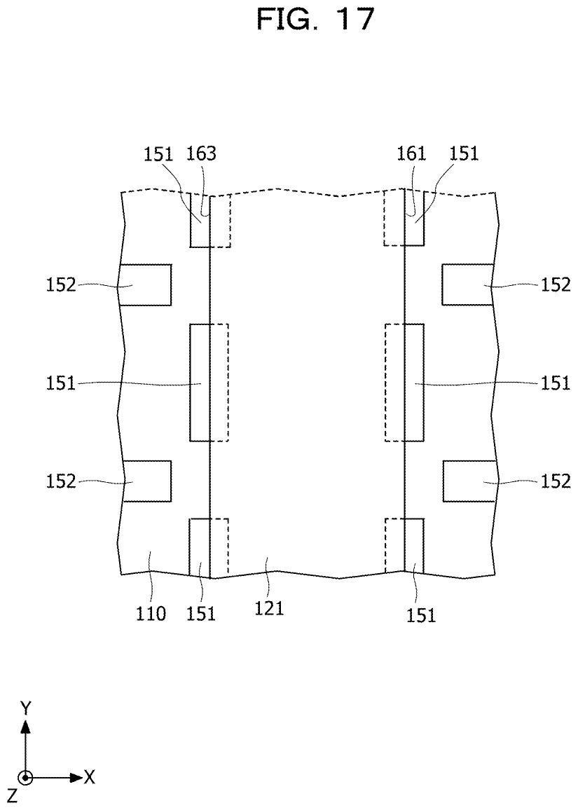

Next, as illustrated in FIG. 17, the two dimensional topological insulator layer 121X is processed to form a plurality of lower topological insulator layers 121. In the process of the two dimensional topological insulator layer 121X, for example, a reactive ion etching (RIE) is performed. As an etching gas, for example, a fluorocarbon gas is used.

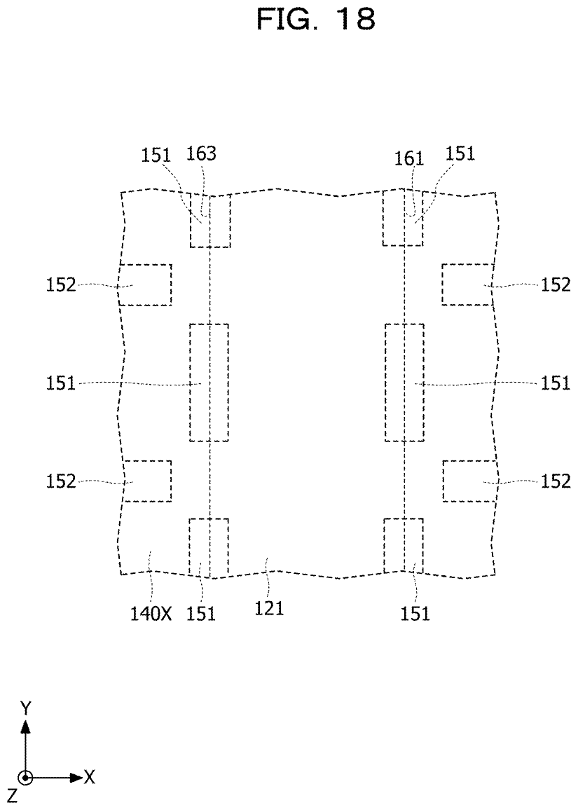

Thereafter, as illustrated in FIG. 18, an etching stopper 140X is provided above the substrate 110 so as to cover the lower topological insulator layer 121. The etching stopper 140X may be provided by, for example, separately growing the etching stopper 140X on a growing substrate (not illustrated) and transferring the etching stopper 140X from the growing substrate.

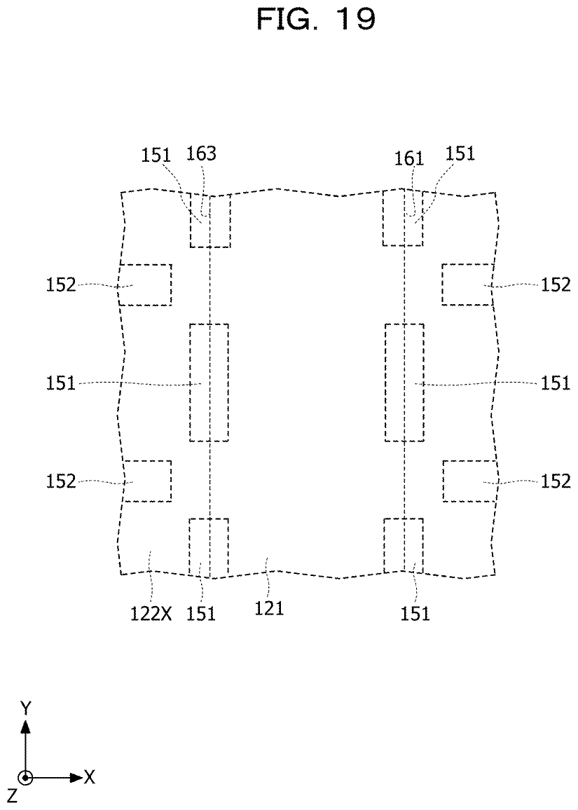

Subsequently, as illustrated in FIG. 19, a two dimensional topological insulator layer 122X is provided over the etching stopper 140X. The two dimensional topological insulator layer 122X may be provided by, for example, separately growing the two dimensional topological insulator layer 122X on a growing substrate (not illustrated) and transferring the two dimensional topological insulator layer 122X from the growing substrate.

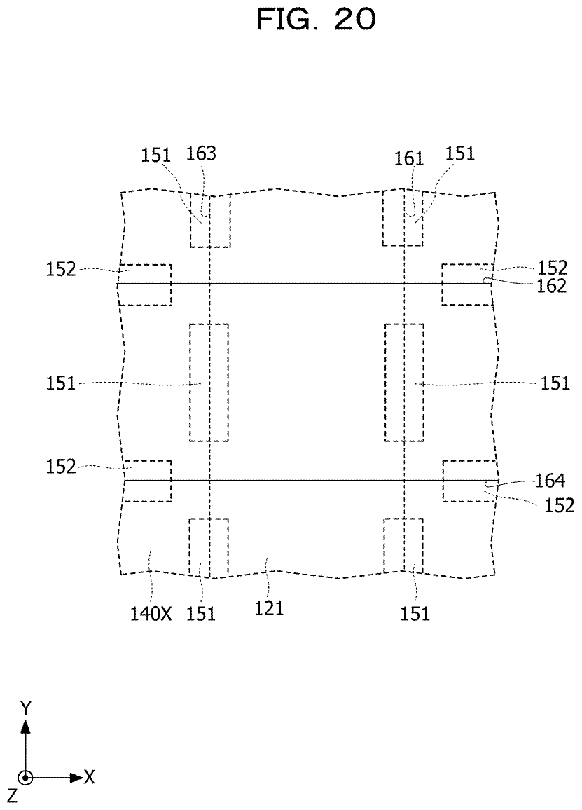

Next, as illustrated in FIG. 20, the two dimensional topological insulator layer 122X is processed to form the plurality of upper topological insulating layers 122. The two dimensional topological insulating layer 122X is processed by, for example, RIE. As the etching gas, for example, a fluorocarbon gas is used. At this time, the lower topological insulator layer is protected by the etching stopper 140X.

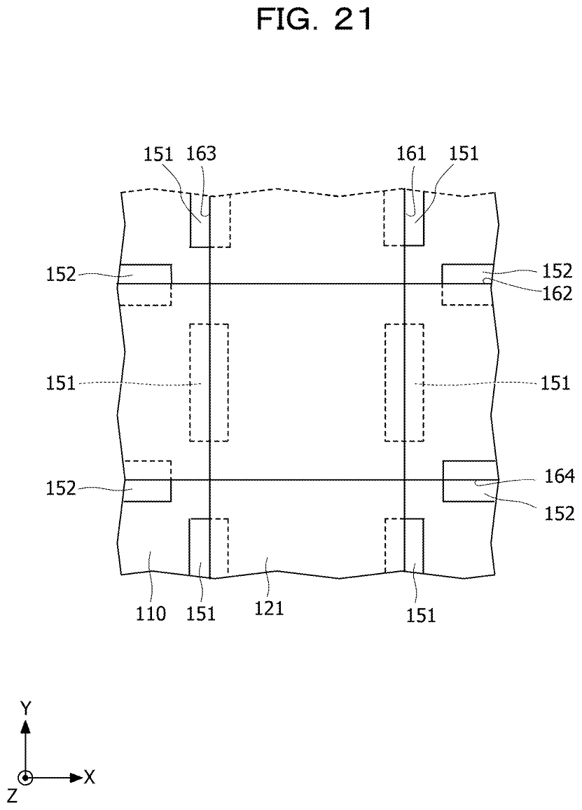

Thereafter, as illustrated in FIG. 21, the etching stopper 140X is processed to remove a portion of the etching stopper 140X exposed from the upper topological insulator layer 122, thereby leaving the etching stopper 140 between the lower topological insulator layer 121 and the upper topological insulator layer 122 (see FIGS. 11 and 12). In the process of the etching stopper 140X, for example, RIE is performed. As the etching gas, for example, an oxygen gas is used.

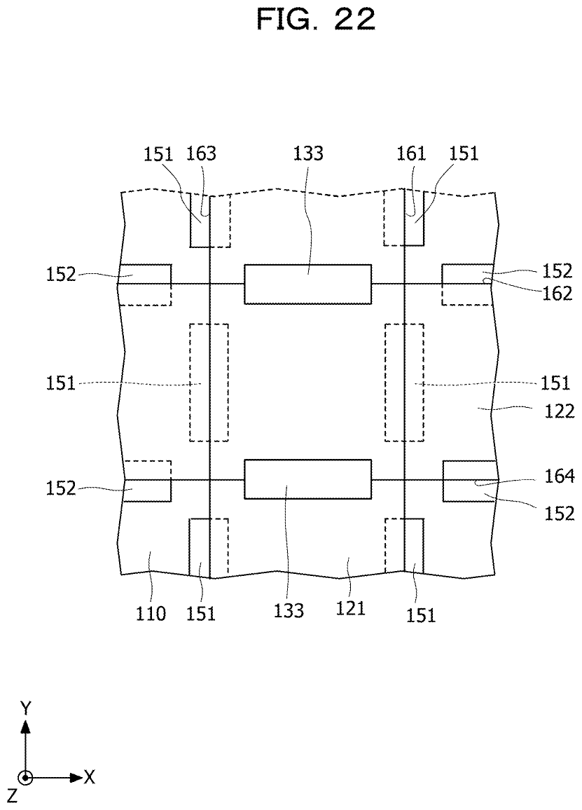

Subsequently, as illustrated in FIG. 22, a laminate of the cap layer 153 and the upper s-wave superconductor layer 133 is formed over the upper topological insulator layer 122 (see FIG. 11).

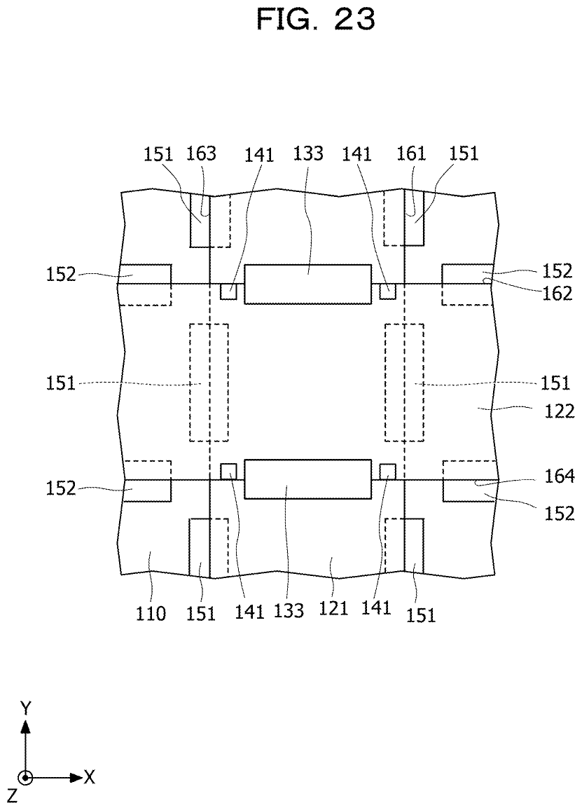

Next, as illustrated in FIG. 23, a plurality of magnetic electrodes 141 are formed over the upper topological insulator layer 122.

In this way, the quantum bit 2 according to the second embodiment may be manufactured.

### Third Embodiment

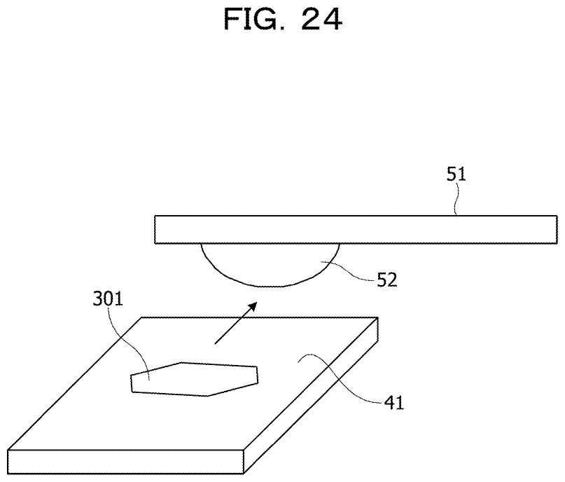

Next, a third embodiment will be described. The third embodiment relates to a method for manufacturing a quantum bit. FIGS. 24 to 28 are schematic views illustrating the method for manufacturing the qubit according to the third embodiment.

First, as illustrated in FIG. 24, an h-BN layer 301 is formed over a growing substrate 41, and the h-BN layer 301 is attached to a transparent polymer mass 52 provided over a slide glass 51.

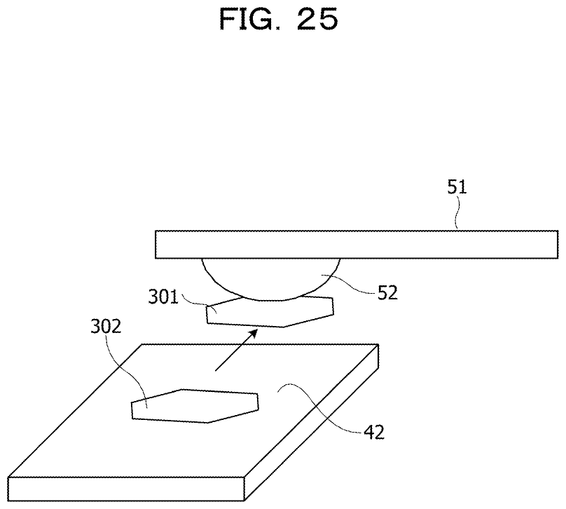

A WTe₂ layer 302 is then formed over the growth substrate 42, and the WTe₂ layer 302 is attached to the h-BN layer 301, as illustrated in FIG. 25. The WTe₂ layer 302 may be formed by, for example, a pulse laser deposition (PLD) method, a molecular beam epitaxy method or the like. The WTe₂ layer 302 separated from the single crystal WTe₂ may be used.

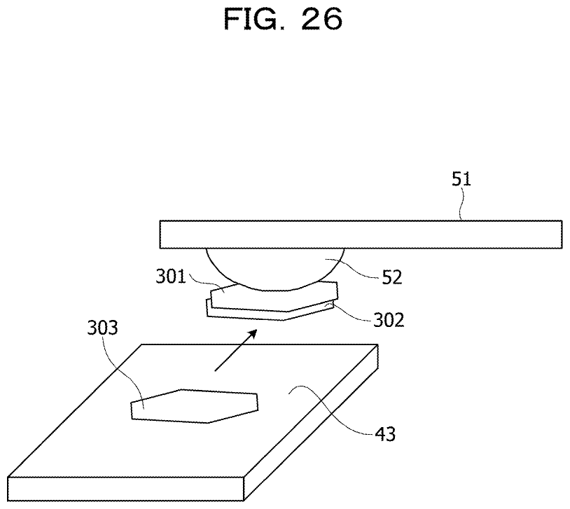

Thereafter, as illustrated in FIG. 26, an h-BN layer 303 is formed over the growing substrate 43, and the h-BN layer 303 is attached to the WTe₂ layer 302.

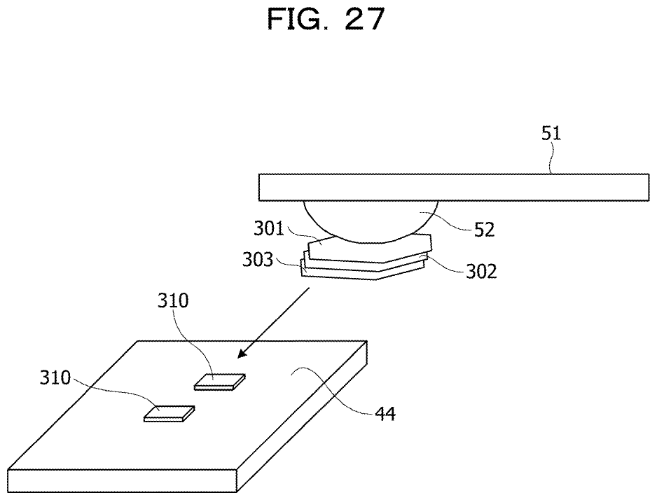

Subsequently, as illustrated in FIG. 27, an s-wave superconductor layer 310 is formed over the substrate 44, and a laminate of the h-BN layer 301, the WTe₂ layer 302 and the h-BN layer 303 is pressed against the s-wave superconductor layer 310.

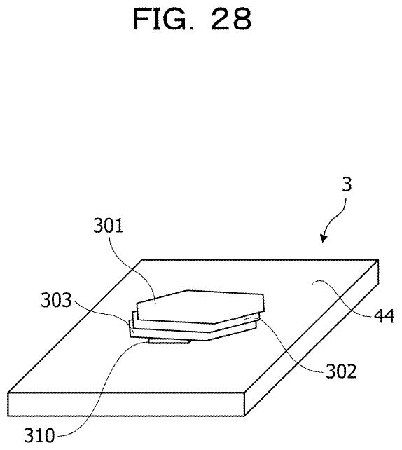

Next, as illustrated in FIG. 28, the transparent polymer mass 52 is removed from the h-BN layer 301. As a result, the laminate of the h-BN layer 301, the WTe₂ layer 302, and the h-BN layer 303 is transferred onto the substrate 44.

In this way, the quantum bit 3 in which the h-BN layer 301 is sandwiched between the s-wave superconductor layer 310 and the WTe₂ layer 302 which is a topological insulator may be manufactured.

### Fourth Embodiment

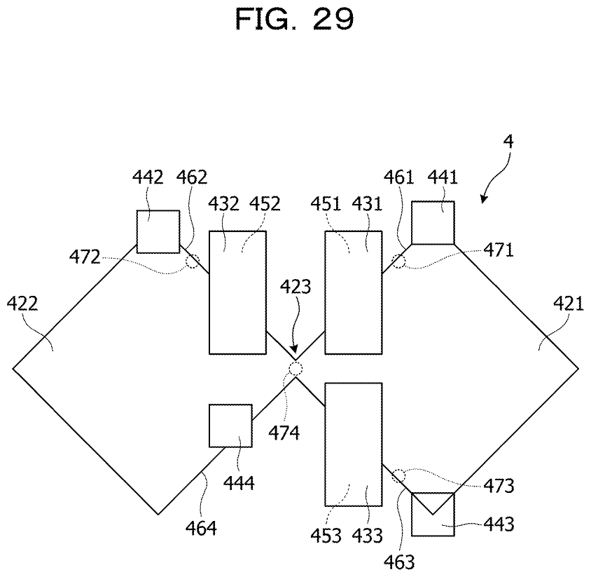

Next, a fourth embodiment will be described. FIG. 29 is a schematic diagram illustrating a quantum bit according to the fourth embodiment.

As illustrated in FIG. 29, the quantum bit 4 according to the fourth embodiment includes a topological insulator layer 421 having a rectangular planar shape and a topological insulator layer 422 having a rectangular planar shape. One vertex of the topological insulator layer 421 and one vertex of the topological insulator layer 422 are coupled. When the topological insulator layers 421 and 422 are regarded as one topological insulator layer, a constriction exists in a coupling portion 423 between the topological insulator layer 421 and the topological insulator layer 422.

The topological insulator layer 421 is, for example, a two dimensional topological insulator layer, and has a first edge 461 and a third edge 463 extending from the coupling portion 423. The topological insulator layer 421 may be formed of a single two dimensional topological insulator or may be formed of a plurality of two dimensional topological insulators stacked on each other. The material of the topological insulation layer 421 is, for example, WTe₂.

The topological insulator layer 422 is, for example, a two dimensional topological insulator layer, and has a second edge 462 and a fourth edge 464 extending from the coupling portion 423. The topological insulator layer 422 may be formed of a single two dimensional topological insulator or may be formed of a plurality of two dimensional topological insulators stacked on each other. The material of the topological insulation layer 422 is, for example, WTe₂.

An s-wave superconductor layer 431 is provided above the first edge 461 of the topological insulator layer 421. An s-wave superconductor layer 433 is provided above the third edge 463 of the topological insulator layer 421. The s-wave superconductor layers 431 and 433 are, for example, Nb layers.

A cap layer 451 is provided over a lower surface of the s-wave superconductor layer 431. The cap layer 451 is in direct contact with the lower surface of the s-wave superconductor layer 431 and an upper surface of the topological insulator layer 421. The cap layer 451 is, for example, an h-BN layer. The cap layer 451 is provided between the first edge 461 and the s-wave superconductor layer 431. There is no chemical bond between the cap layer 451 and the topological insulator layer 421, and the cap layer 451 is in a state in which the cap layer 451 is physically adsorbed to the topological insulator layer 421. The cap layer 451 and the topological insulator layer 421 may be bonded to each other by the van der Waals bonding. A penetration of the Cooper pairs, via the cap layer 451, into the first edge 461 from the s-wave superconductor layer 431 due to the proximity effect may be enabled. For example, the Cooper pairs may tunnel through the cap layer 451 from the s-wave superconductor layer 431 and penetrate the first edge 461. When the Cooper pairs penetrate the first edge 461, the topological insulator layer 421 becomes to function as a topological superconductor layer.

A cap layer 453 is provided over a lower surface of the s-wave superconductor layer 433. The cap layer 453 is in direct contact with the lower surface of the s-wave superconductor layer 433 and an upper surface of the topological insulator layer 421. The cap layer 453 is, for example, an h-BN layer. The cap layer 453 is provided between the third edge 463 and the s-wave superconductor layer 433. There is no chemical bond between the cap layer 453 and the topological insulator layer 421, and the cap layer 453 is in a state in which the cap layer 453 is physically adsorbed to the topological insulator layer 421. The cap layer 453 and the topological insulator layer 421 may be bonded to each other by the van der Waals bonding. A penetration of the Cooper pairs, via the cap layer 453, into the third edge 463 from the s-wave superconductor layer 433 due to the proximity effect may be enabled. For example, the Cooper pairs may tunnel through the cap layer 453 from the s-wave superconductor layer 433 and penetrate the third edge 463. When the Cooper pairs penetrate the third edge 463, the topological insulator layer 421 becomes to function as a topological superconductor layer.

A cap layer 452 is provided over a lower surface of an s-wave superconductor layer 432. The cap layer 452 is in direct contact with the lower surface of the s-wave superconductor layer 432 and an upper surface of the topological insulator layer 422. The cap layer 452 is, for example, an h-BN layer. The cap layer 452 is provided between the second edge 462 and the s-wave superconductor layer 432. There is no chemical bond between the cap layer 452 and the topological insulator layer 422, and the cap layer 452 is in a state in which the cap layer 452 is physically adsorbed to the topological insulator layer 422. The cap layer 452 and the topological insulator layer 422 may be bonded to each other by the van der Waals bonding. A penetration of the Cooper pairs, via the cap layer 452 into the second edge 462 from the s-wave superconductor layer 432 due to the proximity effect may be enabled. For example, the Cooper pairs may tunnel through the cap layer 452 from the s-wave superconductor layer 432 and penetrate the second edge 462. When the Cooper pairs penetrate the second edge 462, the topological insulator layer 422 becomes to function as a topological superconductor layer.

Magnetic layers 441 and 443 are provided over the topological insulator layer 421. The magnetic layer 441 is provided at an end portion of the first edge 461 on a side opposite to the coupling portion 423. The magnetic layer 443 is provided at an end portion of the third edge 463 on the opposite side to the coupling portion 423. In a plan view, a laminate of the s-wave superconductor layer 431 and the cap layer 451 is present between the magnetic layer 441 and the coupling portion 423, and a laminate of the s-wave superconductor layer 433 and the cap layer 453 is present between the magnetic layer 443 and the coupling portion 423. The magnetic layers 441 and 443 generate a magnetic field that extends into the topological insulator layer 421. The material of the magnetic layers 441 and 443 is, for example, Fe, Co, or Ni.

Magnetic layers 442 and 444 are provided over the topological insulator layer 422. The magnetic layer 442 is provided at an end portion of the second edge 462 on the side opposite to the coupling portion 423. The magnetic layer 444 is provided on the fourth edge 464. In a plan view, a laminate of the s-wave superconductor layer 432 and the cap layer 452 is provided between the magnetic layer 442 and the coupling portion 423. The material of the magnetic layers 442 and 444 is, for example, Fe, Co, or Ni.

In the quantum bit 4, a portion between the magnetic layer 441 and the laminate of the s-wave superconductor layer 431 and the cap layer 451 in the plan view of the first edge 461 functions as the first region 471 in which the Majorana particles may exist. A portion between the magnetic layer 442 and the laminate of the s-wave superconductor layer 432 and the cap layer 452 in a plan view of the second edge 462 functions as a second region 472 in which the Majorana particles may exist. A portion between the magnetic layer 443 and the laminate of the s-wave superconductor layer 433 and the cap layer 453 in a plan view of the third edge 463 functions as a third region 473 in which the Majorana particles may exist. Further, the coupling portion 423 functions as a fourth region 474 in which the Majorana particles may exist.

In the fourth embodiment, the cap layer 451 is provided on the lower surface of the s-wave superconductor layer 431, the cap layer 452 is provided on the lower surface of the s-wave superconductor layer 432, and the cap layer 453 is provided on the lower surface of the s-wave superconductor layer 433. Therefore, as in the first embodiment, the disturbance of the electron state of each of the topological insulator layers 421 and 422 may be suppressed, and the Majorana particles may be stably generated.

### Fifth Embodiment

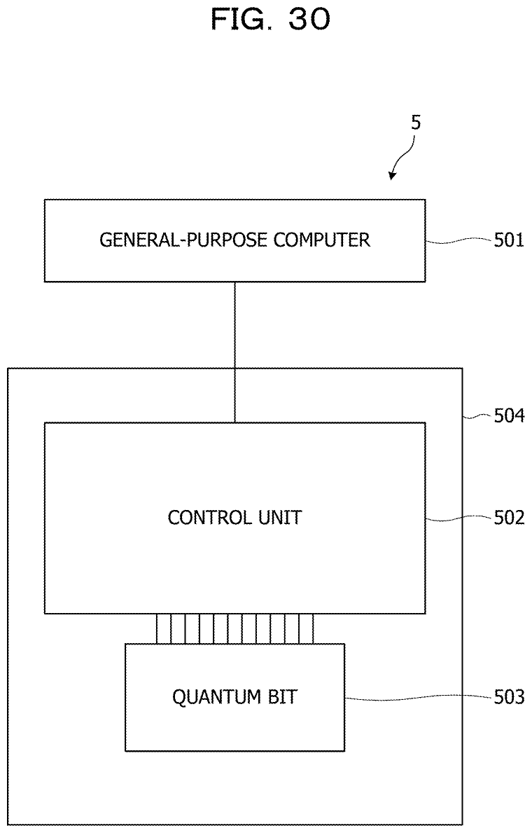

Next, a fifth embodiment will be described. The fifth embodiment relates to a quantum computer. FIG. 30 is a diagram illustrating a quantum computer according to the fifth embodiment.

The quantum computer 5 according to the fifth embodiment includes a general-purpose computer 501, a control unit 502, and a quantum bit 503. The control unit 502 controls the quantum bit 503 based on a control signal from the general-purpose computer 501. As the quantum bit 503, the quantum bit according to any one of the first to fourth embodiments is used. The control unit 502 and the quantum bit 503 are housed in a cryostat 504.

The quantum computer 5 may perform a stable quantum computation.

Note that in the present disclosure, the material of the first layer, for example, the cap layer in the embodiment is not limited to h-BN. If the material of the first layer is h-BN, the first layer is preferably not thicker than 1 nm.

For example, the first layer may be a Nb₂O₅ layer, a Nb₂O₃ layer, a NbO₂ layer, or the like. When the first layer is an oxidic layer, it is preferably not thicker than 1 nm. The oxide layer may be deposited on an Nb layer used as the s-wave superconductor layer, or may be formed by an oxidation of the Nb layer. When the Nb layer is oxidized, a surface of the Nb layer is terminated with O atoms.

For example, the first layer may be a nitride layer such as an NbN layer or a TiN layer. Since the NbN layer functions as a superconductor, it may be relatively thick. Further, a part of the NbN layer may be made to function as the first s-wave superconductor layer. The nitride layer may be deposited over the Nb layer used as the s-wave superconductor layer, may be formed by nitridation of the Nb layer, or may be formed directly over the substrate. When the nitridation of the Nb layer is performed, the surface of the Nb layer is terminated with N atoms.

For example, the first layer may be a graphene layer or graphite. If the first layer is the graphene layer or the graphite, the first layer is preferably not thicker than 1 nm. The graphene layer or the graphite may be provided over the Nb layer used as the s-wave superconductor layer by a transfer or the like, or may be formed by dissolving carbon (C) in the Nb layer and precipitating C. The graphene layer includes one or more graphenes stacked on each other.

For example, the first layer may be a normal metal layer such as an Au layer or a Pt layer. When the first layer is a normal metal layer, the first layer is preferably less than or equal to 5 nm. The normal metal layer may be deposited over the Nb layer used as the s-wave superconductor layer.

The first layer may contain a combination of these plural kinds.

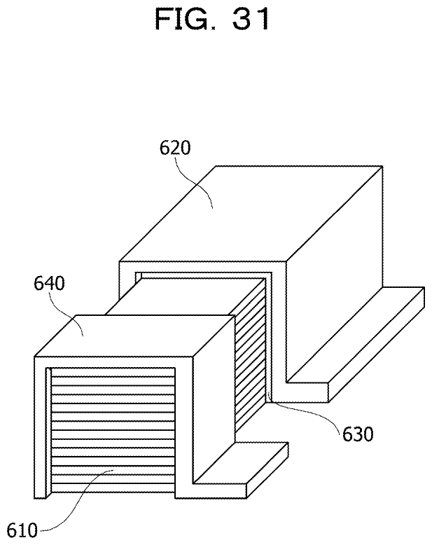

Further, the first topological insulator layer is not limited to the two dimensional topological insulator layer, and may be a higher-order topological insulator layer. FIG. 31 is a schematic diagram illustrating a quantum bit including the high-order topological insulator layer.

The quantum bit 6 illustrated in FIG. 31 includes a higher-order topological insulator layer 610 having a rectangular parallelepiped shape, an s-wave superconductor layer 620, a cap layer 630, and a magnetic layer 640. The cap layer 630 covers a portion of the higher-order topological insulator layer 610, and the s-wave superconductor layer 620 covers the cap layer 630. The cap layer 630 is in direct contact with the higher-order topological insulator layer 610 and the s-wave superconductor layer 620. The materials of the higher-order topological insulating layer 610, the s-wave superconductor layer 620, and the cap layer 630 are, for example, WTe₂, Nb, or h-BN. The magnetic layer 640 covers a part of the higher order topological insulator layer 610 while being separated from the cap layer 630. In a portion of the higher-order topological insulator layer 610 between the cap layer 630 and the magnetic layer 640, the Majorana particles may exist at two hinges (ridgelines) positioned diagonally.

Also in the quantum bit 6, since the cap layer 630 which is appropriate is provided between the s-wave superconductor layer 620 and the high-order topological insulator layer 610, it is possible to suppress the disturbance of the electronic state of the high-order topological insulator layer 610, and it is possible to stably generate the Majorana particles.

Further, the material of the topological insulator layer is not limited to WTe₂. For example, other topological insulators or Weil semimetals may be used as the material of the topological insulator layer.

Although the preferred embodiments and the like have been described in detail above, the present disclosure is not limited to the above-described embodiments and the like, and various modifications and substitutions may be made to the above-described embodiments and the like without departing from the scope described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A Majorana quantum bit, comprising
a first topological insulator layer including a first edge;
a first s-wave superconductor layer; and
a first layer provided between the first edge and the first s-wave superconductor layer and which allows cooper pairs to enter the first edge from the first s-wave superconductor layer.

2. The Majorana quantum bit according to claim 1, wherein the first layer is physically adsorbed to the first topological insulator layer.

3. The Majorana quantum bit according to claim 1, wherein the first layer has a state density over a Fermi surface.

4. The Majorana quantum bit according to claim 1, wherein the first layer includes a Nb₂0₅ layer, a Nb₂O₃ layer, a NbO₂ layer, a NbN layer, a TiN layer, a hexagonal boron nitride layer, a graphene layer, a graphite, an Au layer, a Pt layer, or any combination the Nb₂O₅ layer, the Nb₂O₃ layer, the NbO₂ layer, the NbN layer, the TiN layer, the hexagonal boron nitride layer, the graphene layer, the graphite, the Au layer and the Pt layer.

5. The Majorana quantum bit according to claim 1, wherein the first topological insulator layer includes a two dimensional topological insulator or a higher-order topological insulator.

6. The Majorana quantum bit according to claim 1, further comprising a first magnetic layer that generates a magnetic field which extends to the first topological insulator layer.

7. The Majorana quantum bit according to claim 1, wherein the first layer and the first topological insulator layer are bonded to each other by a van der Waals force.

8. The Majorana quantum bit according to claim 1, wherein the first topological insulator layer extends in a first direction and includes:
a second topological insulator layer that includes a second edge and extends in a second direction which intersects the first direction;
a second s-wave superconductor layer;
a second layer provided between the second edge and the second s-wave superconductor layer and which allows the cooper pairs to enter the second edge from the second s-wave superconductor layer; and
a first region in which a Majorana particle exists in a portion of the first edge which overlaps the second edge in a plan view,
the second topological insulator layer includes a second region in which the Majorana particle exists in a portion of the second edge which overlaps the first edge in a plan view, and
the Majorana particle in the first region and the Majorana particle in the second region are exchangeable.

9. The Majorana quantum bit according to claim 8, wherein the second layer is physically adsorbed to the second topological insulator layer.

10. The Majorana quantum bit according to claim 8, wherein the second layer has a state density over a Fermi surface.

11. The Majorana quantum bit according to claim 8, wherein the second layer includes a Nb₂O₅ layer, a Nb₂O₃ layer, a NbO₂ layer, a NbN layer, a TiN layer, a hexagonal boron nitride layer, a graphene layer, a graphite, an Au layer, a Pt layer, or any combination the Nb₂O₅ layer, the Nb₂O₃ layer, the NbO₂ layer, the NbN layer, the TiN layer, the hexagonal boron nitride layer, the graphene layer, the graphite, the Au layer and the Pt layer.

12. The Majorana quantum bit according to claim 8, wherein the second topological insulator layer includes a two dimensional topological insulator or a higher-order topological insulator.

13. The Majorana quantum bit according to claim 8, further comprising a second magnetic layer that generates a magnetic field which extends to the second topological insulator layer.

14. The Majorana quantum bit according to claim 8, wherein the second layer and the second topological insulator layer are bonded to each other by a van der Waals force.

15. A quantum computer comprising, comprising:
a Majorana quantum bit including:
a first topological insulator layer including a first edge;
a first s-wave superconductor layer; and
a first layer provided between the first edge and the first s-wave superconductor layer and which allows cooper pairs to enter the first edge from the firsts-wave superconductor layer; and
a processor coupled to the Majorana quantum bit and configured to control the Majorana quantum bit.
